(19) United States
(12) Patent Application Publication
(10) Pub. No.: US 2026/0146385 A1
(43) Pub. Date: May 28, 2026

(54) Multifunctional Printer for Direct Printing Metals on Fabrics

(71) Applicant: University of South Florida, Tampa, FL (US)

(72) Inventors: Arash Takshi, Tampa, FL (US); Ehsan Ollah Sheybani, Tampa, FL (US)

(21) Appl. No.: 19/448,824

(22) Filed: Jan. 14, 2026

Related U.S. Application Data
(63) Continuation of application No. PCT/US2024/041692, filed on Aug. 9, 2024.
(60) Provisional application No. 63/518,514, filed on Aug. 9, 2023.

(51) Int. Cl. D06P 5/20; B41J 2/44; B41J 3/407; B41J 3/44; B41J 11/00; B41J 11/06; D06P 5/30; G06T 7/00; G06T 7/90; H05K 1/03; H05K 3/18

(52) U.S. Cl. CPC D06P 5/2016; B41J 2/442; B41J 3/4078; B41J 3/44; B41J 11/0015; B41J 11/0095; B41J 11/06; D06P 5/2005; D06P 5/30; G06T 7/0004; G06T 7/90; H05K 1/038; H05K 3/188; G06T 2207/10024; G06T 2207/10056; G06T 2207/30144; G06T 2207/30232; H05K 2203/107

(57) ABSTRACT

The present invention relates to a multifunctional printer system designed for printing electronic circuits directly onto fabrics, ideal for creating wearable electronics. This system integrates a laser burner, a dual-tube Hydrogen Evolution Assisted (HEA) electroplating nozzle, and a passivation nozzle into a single printer head. The laser burner creates conductive templates on the fabric by burning specific patterns, which are then metalized using the HEA electroplating nozzle to apply copper. This process is enhanced by hydrogen evolution, which improves the quality of copper deposition. Following metalization, an insulating material is applied over the copper patterns using the passivation nozzle to protect and insulate the electronic circuits. The system includes a control unit equipped with a digital microscope and image processing capabilities, enabling real-time monitoring and dynamic adjustment of printing parameters. This approach allows for efficient, precise, and scalable production of integrated electronic textiles.

### PRIORITY CLAIM

This application is a continuation of and claims priority to International Patent Application No. PCT/US24/41692, entitled “Multifunctional Printer for Direct Printing Metals on Fabrics”, filed on Aug. 9, 2024, which claims priority to U.S. Provisional Patent Application No. 63/518,514 filed Aug. 9, 2023, entitled “Multifunctional Printer for Direct Printing Metals on Fabrics”,

### BACKGROUND OF THE INVENTION

### Field of the Invention

This invention relates generally to printing systems. More specifically, it relates to a multifunctional printer capable of printing electronic circuits directly onto fabrics for the development of wearable electronics.

### Brief Description of the Prior Art

In the rapidly evolving field of wearable electronics, the integration of smart technologies into clothing is increasingly sought after for a broad spectrum of applications, including medical monitoring, athletic performance tracking, and military operations. These sophisticated garments, equipped with a variety of sensors and devices, serve diverse purposes—from monitoring patients'health parameters remotely to recording the physical activities of soldiers or athletes, and even administering therapeutic treatments such as physiotherapy or controlled drug delivery. This burgeoning demand for functional wearables underscores the need for efficient and reliable methods to incorporate electronic elements into fabrics.

Traditionally, the methods to integrate electronics into textiles have involved either stitching or gluing electronic components to fabrics, and using wires or conductive threads to establish electrical interconnections. Each of these techniques, however, carries significant limitations that hinder their practicality and effectiveness in producing wearable electronics that are both comfortable and functional.

Wires, for instance, while being reliable conductors, severely compromise the flexibility and comfort of the garment. Their rigid and unyielding nature makes them unsuitable for integration into clothing that needs to maintain softness and conformability to the human body. This is particularly critical in medical and athletic applications where comfort and non-intrusiveness are paramount.

On the other hand, conductive threads offer more flexibility and can be more easily sewn into fabrics, mimicking traditional textile yarns. However, they fall short in terms of electrical performance. Conductive threads typically exhibit high resistivity and are not well-suited for long interconnects required in complex electronic circuit designs. This limitation is a significant drawback as it affects the efficiency and reliability of the power and data transmission across the wearable device, crucial for applications requiring real-time data tracking and processing.

Moreover, both methods—using wires and conductive threads—face considerable challenges in terms of creating durable and reliable connections between the electronic components themselves. Traditional soldering techniques are generally impractical for use on textiles due to the heat-sensitive nature of most fabric materials which can degrade or burn under high temperatures required for soldering. Alternative methods such as using conductive adhesives or mechanical connectors often result in connections that lack long-term durability and robustness, especially under the stress of regular use and laundering which wearable electronics are typically subjected to.

The limitations inherent in these traditional methods have posed a substantial barrier to the scalability and practical application of wearable electronics. The need for a solution that can seamlessly integrate electronic components and their interconnections into textiles without compromising the fabric's flexibility, comfort, or the overall performance of the electronics is evident. This is particularly pressing given the increasing demand for sophisticated wearable devices capable of supporting a wide range of functionalities.

Some companies offer specific wearable products. Their technologies for manufacturing wearable electronics rely on the lamination of flexible printed circuit boards or designing a pigeonhole to place a small electronic circuit. The approaches are practical with a single piece of electronics being attached to the garment, but for distributed sensors, currently, companies either sew conductive threads or laminate wires. Wires are not comfortable (sacrificing the flexibility of the garment) and conductive threads are not suitable for long interconnects especially if large currents are needed. Additionally, soldering is a challenge for sown conductive threads.

In addition to sewing threads and laminating wires, there are a number of scientific publications reporting the successful integration of a piece of electronics into fabrics towards the development of wearable electronics. However, the majority of them demonstrated a single piece of electronics (not a distributed sensor network) or simple circuit layouts with short interconnects. Alternative to sewing conductive threads, three major approaches have been presented in the scientific works: (1) inkjet/silkscreen printing of conductive inks; (2) direct ink write (DIW) also known as hybrid 3D printing; and (3) laser-induced graphene (LIG). Using commercially available inkjet/silkscreen printers and using conductive inks, the fabrication method is achievable. However, the interconnects are highly resistive, suitable only for short interconnects carrying low currents. DIW is an additive manufacturing method in which ink is dispensed out of a nozzle with a controlled flow rate as the nozzle follows a CAD-designed pattern. Harvard University and Air Force Research Labs (AFRL) have demonstrated the application of DIW for printing silver paste ink on fabrics for the development of wearable electronics. The poor adhesion of the printed layer to fabrics and compatibility of the process with various fabrics are technical problems that have to be addressed. Also, the cost of silver compared to copper is a significant factor in a competitive market. Considering the fabrication cost, the laser treatment method (LIG) is inexpensive and easy to apply but produces high resistive interconnects.

What is needed in the art is a LIG method for producing the conductive template and then metalizing the surface with the devised HEA method. This offers an inexpensive fabrication method for designing highly conductive patterns/interconnect on various fabrics.

In this specification, where a document, act or item of knowledge is referred to or discussed, this reference or discussion is not an admission that the document, act or item of knowledge or any combination thereof was at the priority date, publicly available, known to the public, part of common general knowledge, or otherwise constitutes prior art under the applicable statutory provisions; or is known to be relevant to an attempt to solve any problem with which this specification is concerned.

All referenced publications are incorporated herein by reference in their entirety. Furthermore, where a definition or use of a term in a reference, which is incorporated by reference herein, is inconsistent or contrary to the definition of that term provided herein, the definition of that term provided herein applies and the definition of that term in the reference does not apply.

### BRIEF SUMMARY OF THE INVENTION

The present invention details a multifunctional printer system designed to fabricate electronic circuits directly onto fabric substrates, with particular applicability in the development of wearable electronics. This system integrates several key components into a single, cohesive framework, performing a sequential multi-step process for creating highly conductive and durable electronic textiles. The invention encompasses various technologies and methods that address and overcome the limitations of existing approaches in the field of wearable electronics, traditionally involving separate and often inefficient processes.

Central to the invention is the design and implementation of a multifunctional printer head. This printer head includes a laser burner, a dual-tube Hydrogen Evolution Assisted (HEA) electroplating nozzle, and a passivation nozzle, each serving a specific function within the overall process. The laser burner is responsible for creating the initial conductive template on the fabric by burning a precise pattern into the fabric's surface. This process carbonizes the material, rendering it conductive. The laser's programmability allows for high-precision patterning, essential for creating complex circuit layouts required for advanced electronic functionalities. Specifically, the laser operates with the capability to adjust power settings based on the type of fabric being processed, ensuring the right balance between creating conductive patterns and maintaining the structural integrity of the fabric. For instance, a medium power laser (40 W) is typically used to burn patterns into natural fabrics like cotton or those pre-treated with a lignin solution to form graphene or graphite, which are conductive.

Following the laser-based patterning, the dual-tube HEA electroplating nozzle is employed to metallize the conductive templates. This nozzle, innovative in its design, features two distinct channels: a feeding tube and a suction tube. The feeding tube, typically with a diameter between 0.5 to 2 mm, dispenses the electrolyte solution at a controlled rate, while the suction tube removes excess electrolyte to maintain a clean working environment. The system uses an aqueous-based electrolyte composed of 0.5 M CuSO₄ (copper sulfate) and 1.0 M H₂SO₄ (sulfuric acid). This electrolyte is injected through the feeding tube at a rate as low as 1 mL/hour to form a meniscus at the tip of the nozzle, which touches the conductive pattern on the fabric. The dual-tube design is critical for maintaining the quality of the electrolyte and preventing contamination or excess build-up on the fabric.

The HEA process is particularly notable for its efficiency in copper deposition. By applying a voltage greater than 1.23 V, which is the threshold for water electrolysis, the system initiates hydrogen evolution at the cathode. This hydrogen evolution generates convection within the electrolyte, significantly enhancing the rate of copper deposition. The HEA electroplating method can achieve lateral copper growth rates exceeding 370 μm/s, which is more than three orders of magnitude faster than conventional electroplating methods. The resulting copper layer is not only highly conductive but also well-adhered to the fabric, integrating nanostructures that diffuse into the fibers of the textile. The close integration of the copper into the fabric's structure ensures that the printed circuits can withstand mechanical stresses such as bending, stretching, and washing without significant loss of conductivity or adhesion.

During the HEA electroplating process, the printer head is lowered to position the nozzle approximately 1 to 2 mm above the conductive pattern on the fabric. The proximity of the nozzle ensures precise control over the deposition process, allowing copper to grow only underneath the nozzle. As the process continues, the system carefully monitors the progress through a digital microscope integrated into the printer head. This microscope provides real-time images that are analyzed by the control system to adjust the electroplating parameters dynamically. For example, if the copper deposition appears to be insufficient or uneven, the control system can increase the voltage or adjust the electrolyte injection rate to correct the issue.

The invention also addresses the challenge of connecting electronic components to the fabric. Traditional soldering methods are unsuitable for textiles due to the high temperatures required, which can damage the fabric. To overcome this, the invention employs a unique method of “soldering” at room temperature by growing copper over the terminals of electronic components that have been pre-positioned and glued to the fabric. During this step, the printer head pauses above the component terminals for an extended time, typically between 5 to 20 seconds, to allow copper to grow vertically. The process is monitored in real-time using the integrated microscope, and the nozzle may be moved manually or automatically along the Z-axis to guide the copper growth over the terminals. This method forms a continuous copper structure that securely connects the electronic component to the fabric's conductive pattern. The system's control software can automate this soldering process, adjusting the vertical distance and the pause time based on the specific requirements of the component being integrated.

After the metallization and soldering steps, the final stage of the process involves applying an insulating material over the copper-plated fabric using the passivation nozzle. This layer of insulation is critical for protecting the circuits from environmental damage and mechanical wear, thus extending the durability and functionality of the wearable electronics. The insulating material can be applied using either an inkjet nozzle or a direct ink write (DIW) nozzle, depending on the specific requirements of the application. The passivation layer follows the same CAD-designed pattern as the conductive template, ensuring that only the desired areas are coated, preserving the functionality of the circuits while protecting them from external factors.

The entire operation of the multifunctional printer system is governed by a control system, which maintains the quality and consistency of the printed circuits. The control system is equipped with a digital microscope that captures real-time images of the ongoing processes, including laser patterning, electroplating, and passivation. These images are analyzed by an image processing unit, which continuously monitors the quality of the work being done. For example, the distinct color of copper during electroplating is monitored, and any deviation from the expected hue or texture triggers automatic adjustments to the electroplating parameters. This dynamic adjustment capability is vital for ensuring that each layer of the circuit is deposited correctly, with optimal thickness and adhesion.

Furthermore, the control system incorporates machine learning algorithms that enable it to optimize the printing operations continuously. The system learns from each printing cycle, adjusting its parameters based on the data collected during previous operations. This learning process allows the printer to adapt to different types of fabrics and circuit designs, improving the overall efficiency and quality of the printed electronics. For instance, the system can recognize fabric types that require different laser intensities or electroplating voltages and can adjust these parameters automatically during the printing process.

These and other important objects, advantages, and features of the invention will become clear as this disclosure proceeds. The invention accordingly comprises the features of construction, combination of elements, and arrangement of parts that will be exemplified in the disclosure set forth hereinafter and the scope of the invention will be indicated in the claims.

### BRIEF DESCRIPTION OF THE DRAWINGS

For a fuller understanding of the invention, reference should be made to the following detailed description, taken in connection with the accompanying drawings, in which:

FIG. 1 is a conceptual rendering of the printer system disclosed herein with a multifunctional printer head and smart control system.

FIG. 2 is a diagrammatic, partially elevated view of an embodiment of the invention showing the multifunctional printer head including a laser burner.

FIG. 3 are optical microscope images of copper junctions and copper electrodeposition.

FIG. 4 is a diagrammatic, partially elevated view of an embodiment of the invention showing generation of the conductive template on fabric by laser burning.

FIG. 5 is a diagrammatic, partially elevated view of an embodiment of the invention showing metallization of the conductive template using the devised dual-tube HEA electroplating nozzle.

FIG. 6 is a diagrammatic, partially elevated view of an embodiment of the invention showing the surface of the metalized pattern coated with a passivation layer through a direct ink write.

FIG. 7 is a diagrammatic, partially elevated view of an embodiment of the invention showing the surface of the metalized pattern coated with a passivation layer through an inkjet nozzle.

FIG. 8 is an image from the microscope camera of the invention apparatus during the HEA electroplating process.

FIG. 9 is a diagrammatic process view of an iterative optimization process for various fabric types.

### DETAILED DESCRIPTION OF THE INVENTION

In the following detailed description of the preferred embodiments, reference is made to the accompanying drawings, which form a part thereof, and within which are shown by way of illustration specific embodiments by which the invention may be practiced. It is to be understood that other embodiments may be utilized and structural changes may be made without departing from the scope of the invention.

As used in this specification and the appended claims, the singular forms “a,” “an,” and “the” include plural referents unless the content clearly dictates otherwise. As used in this specification and the appended claims, the term “or” is generally employed in its sense including “and/or” unless the context clearly dictates otherwise.

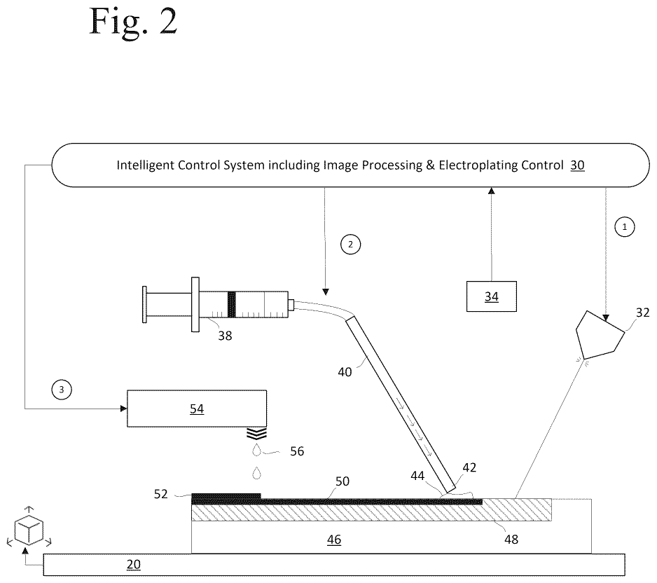

Turning now to FIG. 2, the process of printing a metallic circuit layout on fabrics is a multi-step printing process. In Step 1 (denoted by numeral 1 within a circle), a conductive template 48 has to be applied on the textile 46. The pattern can be applied by laser induction of graphene (LIG). This can be done simply by using a programmable laser 32 engraving machine that can apply a CAD-designed circuit layout. The approach is practical for natural materials such as cotton-based fabrics, but synthetic materials such as polyester, nylon, or composites (e.g., cotton-polyester) require a higher power of the laser that technically burns through the fabric. In the search for finding a solution for various fabric materials, we developed a liquid solution by simply mixing natural lignin in water. The surface of the fabric 46 can be coated with the lignin solution and after drying, a medium power laser (40 W) can convert lignin to graphene/graphite which makes a conductive pattern. Our experimental results show that the laser-made pattern has a high adhesion to the fabric while the rest of the lignin can be washed off. Also, the mechanical stability of the fabric does not change after the laser treatment.

Although laser burning has been demonstrated before for circuit patterning on fabrics, scientific publications in this field have not addressed the technical challenges for practical applications. The two major challenges are the relatively poor conductivity of the carbonized pattern and the challenge in soldering terminals of the electronic devices. As our experimental results show the resistivity of the carbonized lignin on fabric is in the range of kΩ/sq and it varies when the fabric is bent. Such a high resistivity is not suitable for designing a smart garment with distributed sensors on the body of a person (metallic conductivity is required). The second challenge with the carbonized circuit layout is in soldering electronics due to the lack of compatibility between carbon and the metallic pin materials of the electronic devices. Silver paste has been suggested in prototype wearable electronics which is not durable for practical applications. In fact, the ‘solder’ joint becomes the weakest part of the structure resulting in the failure of the whole circuit when the fabric is bent/stretched.

In Step 2, the surface of the conductive template is metalized. The suggested method is HEA copper electroplating as described in U.S. Pat. No. 11,214,884. Generally, for copper electroplating, a copper piece is used as the anode, and the conductive target (in this case our conductive template on fabric) is connected as the cathode. Using an aqueous-based electrolyte (0.5 M CuSO4 and 1.0 M H2SO4) between the two electrodes and applying DC voltage/current, the surface of the cathode coats with copper. However, in conventional electroplating where the voltage difference between the anode and cathode is limited to a few hundred millivolts, the copper growth rate is limited by the mass transfer rate of ions to be less than 100 nm/s. Such a rate is too slow for printing. In contrast, in our devised HEA method, a voltage larger than 1.23 V (potential for water electrolysis) is applied, through which concurrent to the copper deposition, hydrogen evolution occurs at the cathode. The hydrogen evolution generates convection in the liquid enhancing the copper deposition. Also, the generated hydrogen bubbles produce a porous copper structure with nanometer-sized features, presenting the required flexibility needed for wearable electronics while having the conductivity of pure copper. We have shown that the HEA electroplating method can be used for fast printing copper on fabrics reaching a lateral copper growth rate exceeding 370 μm/s (more than three orders of magnitude faster than the conventional electroplating). The final pattern is integrated into the fabric due to the nanostructures of the grown copper layer being diffused into the fiber of the fabric. This method proves to be cost-effective and produces conductive patterns that can be used for long and low-resistance interconnections between distributed sensors on a smart garment. To enhance the durability, it is recommended to coat the metal with a thin insulating material 56 discharged through nozzle 54 to passivate the surface as shown in Step 3 of FIG. 2. Since varnish has been used before for protecting electronic circuits, in the third step, a thin layer of the insulator can be printed over the metalized pattern.

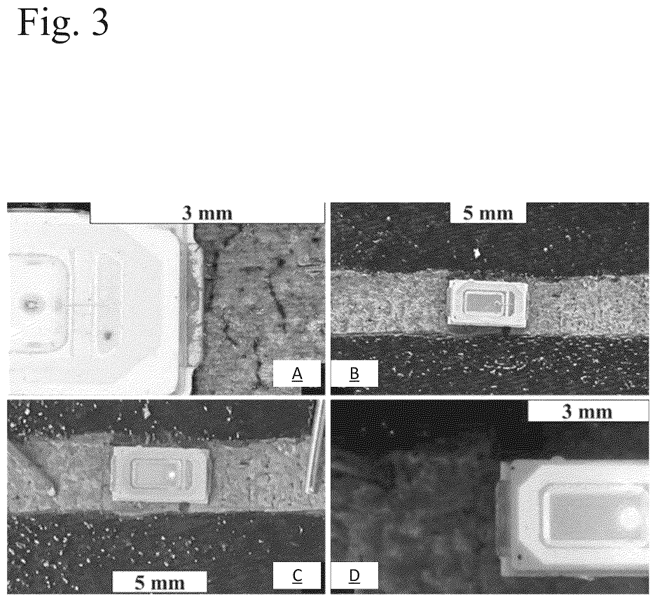

It should be noted that a unique feature of the new manufacturing method is in “soldering” at room temperature by growing copper over the terminals of a glued component to the fabric. FIG. 3 shows a surface mount device (SMD) LED that was integrated into the printed copper on a piece of fabric. Images A and B in FIG. 3 show the LED in an unpowered state and images C and D show the LED powered giving off illumination. The components can be glued to the fabric before or after Step 1 (developing a conductive pattern). During Step 2 (growing copper), the nozzle 42 was kept above the junction for an extended time (˜20 s) to allow copper 50 to grow vertically. As the process was monitored through the microscope camera 34, the nozzle 42 was moved manually along the Z direction to grow copper over the terminals of the device forming a continuous copper structure 50 connecting the device to the electroplated interconnect.

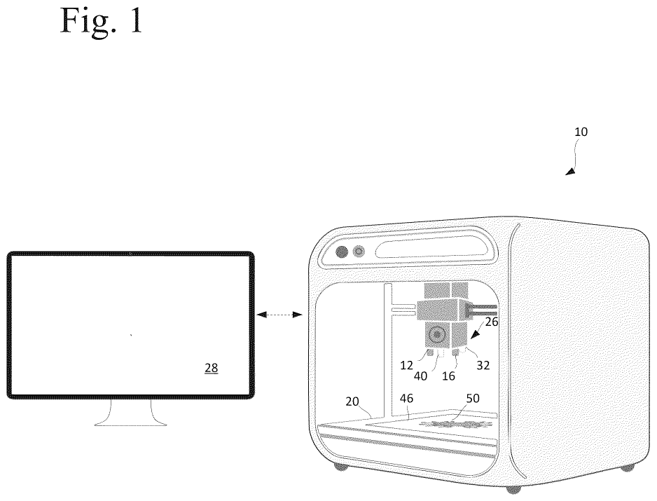

The devised system is a multifunctional printing machine equipped with a smart control system for direct printing copper circuit layouts on fabrics. The process of copper printing is a sequential manufacturing process. As shown in FIG. 1, the invented printing machine 10 consisted of a multi-functional printing head 26 mounted on a motorized xyz stage 20 and equipped with a smart control system 28 using video stream image processing and ML/AI algorithms to achieve high quality printing. The printer head includes: a laser burner 32, a devised “dual-tube” HEA electroplating nozzle 40, a nozzle 54 to print an insulating material 56 (inkjet nozzle or direct write nozzle), and a microscope camera 34.

If it is needed, the fabric of interest can be coated with a water-based solution of lignin and dried before laser printing. As mentioned, some fabric materials convert to conductive carbon after being exposed to a laser beam. But other materials need a coating of lignin.

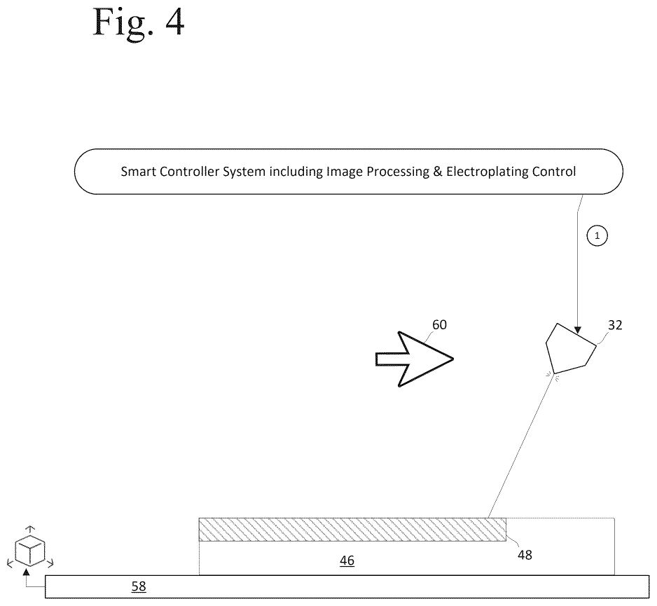

After placing the fabric sample 46 on the printer stage 20, the CAD file including the desired circuit layout 50 can be uploaded to the printer. In step 1, the pattern 50 gets printed on the fabric 46 by controlling the laser beam 32 to generate a conductive template (FIG. 4).

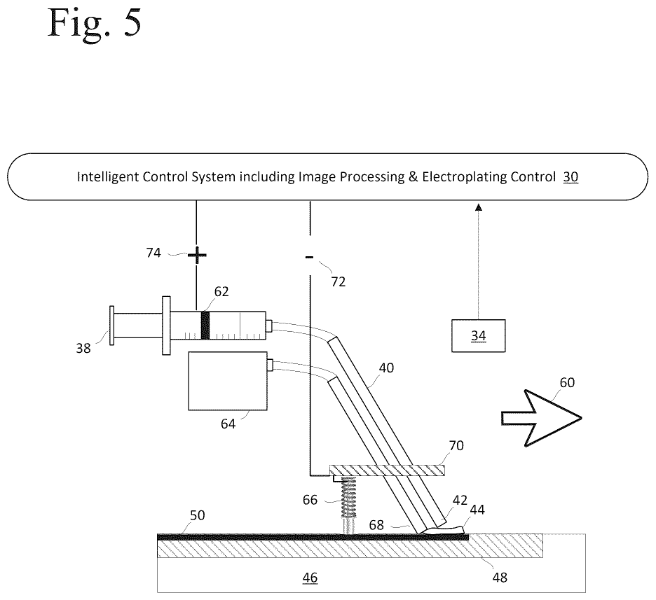

In Step 2, the dual-tube HEA electroplating nozzle 40 follows the same pattern to metalize the surface of the pattern. As shown in FIG. 5, the dual-tube HEA printing system consisted of two tubes (typical diameter of 0.5-2 mm), one for injection of electrolyte (feeding tube) 40 and the other for removing the electrolyte (suction tube 68) from the fabric surface 46. The suction tube 68 is connected to a small suction pump 64 and the feeding tube 40 is connected to a syringe 38 controlled by a syringe pump. The rate of electrolyte circulation is set by the syringe 38 and suction pump 64. A copper disc 62 in the syringe acts as the anode 74, while the conductive pattern on the fabric is the cathode 72. To make a cathode contact, a spring-loaded pin (pogo-pin) 66 is installed on the head of the printer. The installed microscope camera 34 on the printer head is adjusted to monitor the electroplating process at the tip 42 of the feeding nozzle 40. For printing, the printer head is lowered to put the HEA nozzle about 1 to 2 mm above the conductive pattern. In this position, the pogo-pin 66 is making electrical contact with the template as the cathode 72. The syringe pump injects the electrolyte to the tip 42 of the feeding tube 40 (a rate as low as 1 mL/hour) allowing to form a meniscus 44 of the electrolyte to touch the conductive pattern 48 on the fabric 46. However, with the suction line 68, the interface area between the electrolyte and the cathode 72 can be very limited to ensure growing copper only underneath the nozzle 42. Applying a sufficiently large voltage (higher than 1.23 V where water electrolysis) between the anode 74 and the cathode 72, copper starts growing under the nozzle 42. Controlling the motion 60 of the printer head to follow the CAD-designed circuit layout, copper grows over the conductive template at the nozzle 42 moves. The quality of printing is constantly monitored, using the microscope camera 34.

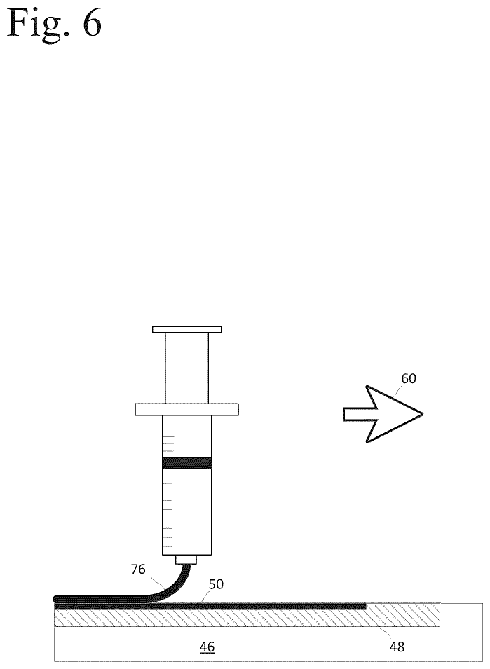

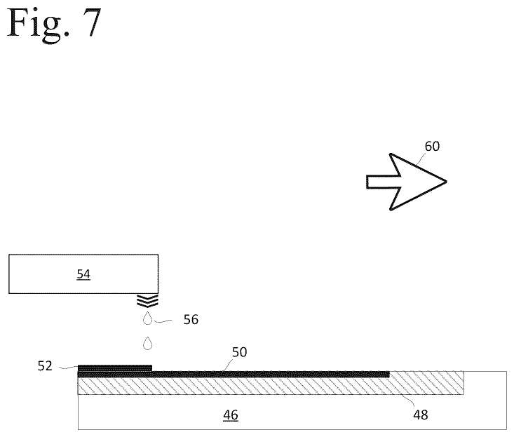

After metallization, in Step 3, the surface of copper can be coated with an insulating material (i.e., varnish) to protect the layout. The nozzle for the passivation printing can be an inkjet nozzle (FIG. 7) or a direct ink write (DIW) nozzle (FIG. 6). While an inkjet printer prints pixels by dispersing droplets of the ink 56 (liquid containing the passivation material), in DIW, there is a continuous stream 76 of ink. In either case, the printer again can follow the same CAD-designed pattern to coat the circuit layout with the insulating material.

As explained, for soldering components, the components can be glued to the fabric 46 prior to loading the fabric on the printer. In Step 2, as the copper grows over the template when it reaches the device terminals, the printer head has to pause for a few seconds (5-20 sec) to allow copper to grow over the terminals of the device. This may require moving the nozzle vertically as copper grows perpendicular to the surface. The process of soldering can be implemented in the software of the printer to automatically adjust the vertical distance and the pause time for soldering. In Step 3, the passivation layer 52 can cover the soldered area 50 to improve the durability of wearable electronics.

While Steps 1 and 3 require parameter adjustments such as the speed of printing or the power of the laser, Step 2 is the most critical step that is expected to produce a highly conductive circuit layout being well adhered to the fabric 46. Our studies show that the quality of the electroplated layer depends on the electroplating voltage, speed of printing (speed of nozzle motion), and injection rate from the syringe pump which all needed to be controlled dynamically for printing highly conductive patterns. Also, it is found that the parameters can be substantially different for different types of fabric due to the materials and structure of the textiles. To ensure effective copper electroplating, the smart control system is designed to implement a feedback mechanism to adjust the parameters dynamically via processing the images from the video streaming of the process.

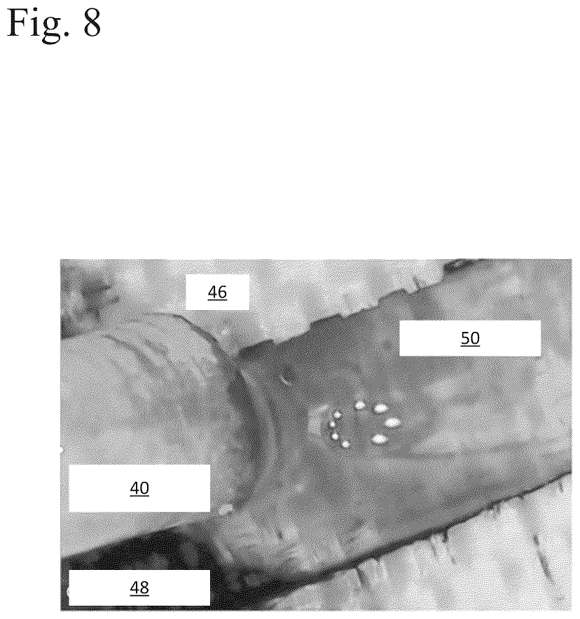

As shown in FIG. 8, due to the distinct color of copper, a simple image processing code can be developed to recognize the copper as it is printed. Also, since the position of the microscope camera is adjusted to monitor the growth of copper right under the nozzle, the image processing load will be limited to a segment of the captured image allowing to run the image processing on a live video stream. A poor coating layer would present a different color/morphology that can be corrected by increasing the electrochemical voltage between the anode and cathode and the electrolyte injection rate. The controlled system can be programmed to constantly monitor the video data and adjust the printing parameters to achieve the color shade associated with the high-quality printing. Also, monitoring the electrochemical current in a feedback loop the voltage will be adjusted to maintain the current at a tested level which guarantees high conductivity of the copper layer.

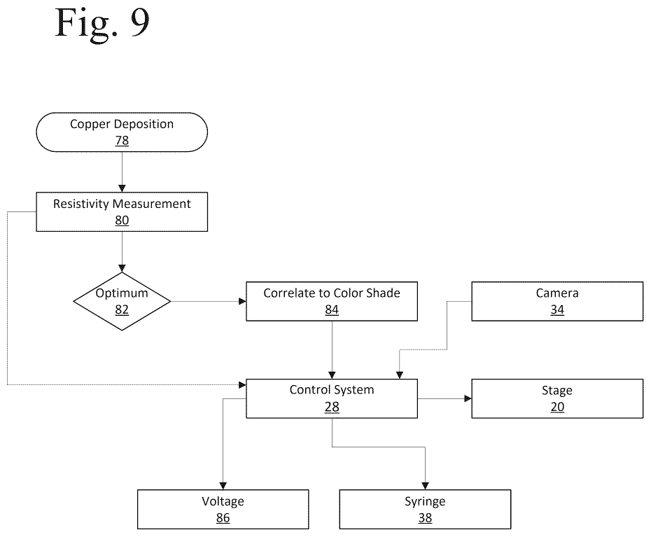

Furthermore, the printing parameters for different types of fabrics can be fine-tuned using an ML model. The control system can train itself based on the image-processed data of the fabric structure and the morphology of the coating. FIG. 9 depicts the process of iterative optimization used in the multifunctional printer system for different fabric types. This process is enabled by a control system 28 that continuously refines printing parameters through real-time feedback loops.

The process begins with copper deposition 78, where the conductive pattern is formed on the fabric. As the copper is deposited, its resistivity 80 is measured. This resistivity is a key indicator of the quality of the printed layer, as lower resistivity corresponds to higher conductivity, which is critical for the performance of electronic textiles.

The system then establishes an optimum 82 value for resistance and what parameters achieved that value for a particular fabric. This is correlated with the color shade 84 of the copper which is monitored by camera 34. The distinct color of copper during deposition allows the control system to use a simple image processing code to identify the quality of the deposition based on color. This correlation helps in fine-tuning the process, ensuring that the printed copper meets the required quality standards.

To find the optimal parameters, the control system 28 adjusts the parameters such as voltage 86, which affects the electrochemical current, and the flow rate of the electrolyte controlled by the syringe pump 38. The camera (34), which monitors the process, plays a role in capturing real-time images that are processed to make these observations and adjustments. The stage (20), which holds the fabric, can also be adjusted based on the feedback to ensure the nozzle is correctly positioned and moved at a speed for optimal printing.

This iterative process is enhanced by an AI/ML-based calibration feature, which further refines the printing process for different types of fabrics. The control system can use previous experimental data and machine learning algorithms to adjust the parameters dynamically. The AI/ML algorithms, including CNN, PCA, and LDA, help in classifying data from various samples, thereby optimizing the printing parameters for each specific fabric type.

In this process, the control system 28 is designed to learn from previous iterations, continuously improving the quality of copper deposition through the feedback loop established by the resistivity measurements and image processing. The ability to correlate color shades with resistivity allows for real-time adjustments to ensure high conductivity, and the AI/ML models further enhance this by adapting the system to various fabric materials and conditions, storing the optimized settings in a library for future use.

Through this iterative optimization, the multifunctional printer can consistently produce high-quality electronic circuits on a variety of fabrics, ensuring that the printed circuits meet the necessary conductivity and durability standards. The control system's ability to monitor and adjust in real-time, combined with the learning capabilities of AI/ML algorithms, makes this process highly efficient and adaptable, setting the stage for scalable production of advanced wearable electronics.

### GLOSSARY OF CLAIMS TERMS

Anode means the positively charged electrode in the electroplating process where oxidation occurs. In the context of the multifunctional printer system, the anode is typically a copper disc placed within the electrolyte solution. During the electroplating process, copper ions from the anode dissolve into the electrolyte and are then deposited onto the cathode, which is the conductive template on the fabric.

Carbonized Conductive Patterns means the electrically conductive patterns created on the fabric by burning the fabric surface with a laser. This process involves the carbonization of the material, converting the fabric's surface into a conductive layer that can be used as the foundation for subsequent metallization. The carbonized patterns exhibit high adhesion to the fabric and form the initial conductive pathways necessary for creating electronic circuits.

Cathode means the negatively charged electrode in the electroplating process where reduction occurs. In the multifunctional printer system, the cathode is the conductive template that has been created on the fabric. When a voltage is applied, copper ions from the electrolyte are reduced and deposited onto the cathode, forming a metalized layer over the carbonized pattern.

Conductive Templates means the initial patterns created on the fabric using a laser burner, which serve as the blueprint for the electronic circuits. These templates are formed by carbonizing the surface of the fabric, making it electrically conductive. The templates are later metalized during the electroplating process to enhance their conductivity and durability.

Conductor means a material that allows the flow of electrical current with minimal resistance. In the context of the multifunctional printer system, the conductor typically refers to the copper deposited onto the fabric's surface during the electroplating process. This copper layer forms the electrical pathways that connect various electronic components integrated into the fabric.

Control System means the integrated system within the multifunctional printer that manages the operation of the printer head components, including the laser burner, HEA electroplating nozzle, and passivation nozzle. The control system is equipped with a digital microscope and image processing capabilities, enabling it to adjust printing parameters dynamically in response to real-time feedback. It may also include machine learning algorithms to optimize the process for different fabrics and circuit designs.

Digital Microscope means a high-resolution camera integrated into the printer head, used for capturing real-time images of the printing process. These images are analyzed by the control system to monitor the quality of the printing and make necessary adjustments. The digital microscope is crucial for ensuring the precision and accuracy of the metalization and passivation processes.

Direct Ink Write (DIW) means an additive manufacturing technique where ink is dispensed from a nozzle in a continuous stream, following a CAD-designed pattern. In the multifunctional printer system, DIW is used for applying the insulating material over the metalized patterns to passivate the surface of the circuits. DIW offers precise control over the application of the insulating material, ensuring uniform coverage.

Electrolyte means the aqueous solution used in the electroplating process to conduct electrical current between the anode and cathode. In the multifunctional printer system, the electrolyte typically consists of 0.5 M CuSO₄ and 1.0 M H₂SO₄, which facilitate the deposition of copper onto the fabric. The electrolyte's composition and flow rate are carefully controlled to ensure consistent and high-quality metalization.

Fabric means the textile material that serves as the substrate for the multifunctional printer system. The fabric can be natural or synthetic, and its surface is prepared to receive the conductive template through a laser burning process. Depending on the type of fabric, additional treatments such as lignin coating may be applied to improve its suitability for laser-induced carbonization.

Feeding Tube means the component of the dual-tube HEA electroplating nozzle responsible for delivering the electrolyte to the fabric surface. The feeding tube injects the electrolyte at a controlled rate to form a meniscus that contacts the conductive template. This tube ensures that the electrolyte is supplied precisely where copper deposition is needed, minimizing waste and enhancing the efficiency of the electroplating process.

Hydrogen Evolution Assisted (HEA) Electroplating means an electroplating method that uses a voltage greater than 1.23 V to initiate both copper deposition and hydrogen evolution at the cathode. This process enhances copper deposition by generating convection within the electrolyte, leading to faster and more uniform metalization. HEA electroplating is particularly effective for creating highly conductive and flexible copper layers on fabric, suitable for wearable electronics.

Insulating Material means the substance applied over the metalized patterns to protect the circuits from environmental damage and mechanical wear. The insulating material, which can be applied using either an inkjet nozzle or a DIW nozzle, forms a protective coating that ensures the long-term durability and reliability of the electronic circuits integrated into the fabric.

Laser Burner means the component of the multifunctional printer system that creates the initial conductive templates on the fabric by burning a specific pattern into the material. The laser burner operates with adjustable power settings to suit different fabric types, converting the surface into carbonized conductive patterns that serve as the foundation for the subsequent electroplating process.

Laser Induction of Graphene (LIG) means a process where a laser is used to convert certain materials, such as lignin-coated fabrics, into graphene. This technique is used in the initial stage of the multifunctional printer system to create conductive templates on fabric substrates. LIG offers a low-cost and effective method for producing conductive patterns with high adhesion to the fabric.

Lignin means an organic polymer used as a coating on certain fabrics to facilitate the laser-induced formation of conductive graphene patterns. When treated with a laser, lignin converts to graphene, creating a conductive surface that adheres well to the fabric. This process is particularly useful for synthetic fabrics that do not carbonize easily on their own.

Machine Learning Algorithms means the computational models integrated into the control system of the multifunctional printer, which enable the system to optimize printing parameters based on historical data and real-time feedback. These algorithms help the printer adapt to different fabric types and circuit designs, improving the consistency and quality of the printed circuits over time.

Meniscus means the curved surface formed by the electrolyte at the tip of the feeding tube in the HEA electroplating nozzle. The meniscus ensures that the electrolyte only contacts the desired area of the conductive template, allowing for precise copper deposition. The shape and stability of the meniscus are crucial for maintaining the accuracy and efficiency of the electroplating process.

Metalized Patterns means the conductive templates on the fabric that have been coated with copper using the HEA electroplating process. These patterns form the electrical circuits that connect various electronic components integrated into the fabric. The metalized patterns exhibit high conductivity and are well-adhered to the fabric, ensuring their durability in wearable electronics.

Motorized Stage means the platform on which the fabric is placed during the printing process. The motorized stage can move in the XYZ directions, allowing the fabric to be precisely positioned relative to the printer head. This stage is controlled by the control system, ensuring that the fabric is always correctly aligned for each step of the process, whether it is laser patterning, electroplating, or passivation.

Passivation Nozzle means the component of the multifunctional printer system responsible for applying the insulating material over the metalized patterns. The passivation nozzle can be either an inkjet nozzle or a DIW nozzle, depending on the application requirements. It ensures that the circuits are adequately protected by coating them with a thin layer of insulator, which guards against environmental and mechanical damage.

Pogo-Pin means a spring-loaded pin used to make electrical contact with the conductive template during the electroplating process. The pogo-pin ensures a stable and consistent connection between the template and the cathode in the HEA electroplating process, facilitating the efficient deposition of copper onto the fabric.

Printer Head means the assembly within the multifunctional printer that houses the laser burner, HEA electroplating nozzle, and passivation nozzle. The printer head is the core functional unit of the system, capable of moving across the fabric to perform each step of the printing process. It is equipped with a digital microscope and is controlled by the system's control unit, ensuring precise operation and high-quality output.

Suction Tube means the component of the dual-tube HEA electroplating nozzle responsible for removing excess electrolyte from the fabric surface. The suction tube works in conjunction with the feeding tube to maintain a controlled and clean electroplating environment, preventing the electrolyte from spreading beyond the desired area and ensuring that copper deposition is limited to the correct regions.

The advantages set forth above, and those made apparent from the foregoing description, are efficiently attained. Since certain changes may be made in the above construction without departing from the scope of the invention, it is intended that all matters contained in the foregoing description or shown in the accompanying drawings shall be interpreted as illustrative and not in a limiting sense.

It is also to be understood that the following claims are intended to cover all of the generic and specific features of the invention herein described, and all statements of the scope of the invention that, as a matter of language, might be said to fall therebetween.

What is claimed is:

1. A multifunctional printer system for printing electronic circuits on fabrics, comprising:
a laser burner configured to generate conductive templates directly on a fabric by burning the fabric surface to create carbonized conductive patterns;
a dual-tube Hydrogen Evolution Assisted (HEA) electroplating nozzle configured to metalize the conductive templates with copper, the nozzle having a feeding tube for dispensing an electrolyte and a suction tube for removing the electrolyte;
a passivation nozzle configured to apply an insulating material over the metalized patterns to passivate the surface of the conductor; and
a control system configured to dynamically adjust the parameters of the laser burner, the HEA electroplating nozzle, and the passivation nozzle based on real-time feedback from an integrated digital microscope.

2. The multifunctional printer system of claim 1, wherein the laser burner is programmable to adjust the intensity and pattern of the laser based on the type of fabric and the desired circuit layout.

3. The multifunctional printer system of claim 1, wherein the dual-tube HEA electroplating nozzle is configured to enhance copper deposition by generating hydrogen evolution at the cathode to induce convection.

4. The multifunctional printer system of claim 1, wherein the control system includes image processing to analyze live images from the digital microscope to monitor and adjust the printing process in real time.

5. The multifunctional printer system of claim 1, wherein the passivation nozzle is configured to apply an insulating varnish to protect the metalized patterns from environmental damage and wear.

6. The multifunctional printer system of claim 1, further comprising a motorized stage for moving the fabric relative to the printer head, wherein the movement is controlled by the control system based on the real-time feedback from the digital microscope.

7. The multifunctional printer system of claim 1, wherein the control system applies machine learning algorithms to optimize the printing parameters responsive to processing different fabric types and electronic circuit designs.

8. The multifunctional printer system of claim 1, wherein the HEA electroplating nozzle includes a pogo-pin to make electrical contact with the conductive pattern.

9. A method for printing electronic circuits on fabrics using a multifunctional printer system, comprising:
generating a conductive template on a fabric by burning the fabric surface with a laser burner to create carbonized conductive patterns;
metalizing the conductive template by applying copper using a dual-tube Hydrogen Evolution Assisted (HEA) electroplating nozzle, which dispenses and removes an electrolyte while generating hydrogen evolution at the cathode to enhance plating;
applying an insulating material over the metalized patterns using a passivation nozzle to passivate the surface of the conductor; and
dynamically adjusting the parameters of the laser burner, the HEA electroplating nozzle, and the passivation nozzle based on real-time feedback from a digital microscope integrated with the control system.

10. The method of claim 9, wherein the laser burner is programmed to adjust the intensity and pattern of the laser based on the type of fabric and the desired circuit layout.

11. The method of claim 9, wherein the HEA electroplating nozzle enhances copper deposition by generating hydrogen evolution at the cathode to induce convection.

12. The method of claim 9, wherein the control system includes image processing of live images received from the digital microscope to adjust the printing process in real time.

13. The method of claim 9, wherein the passivation nozzle applies an insulating varnish to protect the metalized patterns from environmental damage and wear.

14. The method of claim 9, further comprising moving the fabric relative to the printer head using a motorized stage controlled by the control system based on the real-time feedback from the digital microscope.

15. The method of claim 9, wherein the control system utilizes machine learning algorithms to optimize the printing parameters for different fabric types and electronic circuit designs.

16. The method of claim 9, wherein the HEA electroplating nozzle includes a pogo-pin to make electrical contact with the conductive pattern.

17. A multifunctional printer head for printing electronic circuits on fabrics, comprising:
a laser burner for generating conductive templates by burning the fabric surface;
a dual-tube Hydrogen Evolution Assisted (HEA) electroplating nozzle for metalizing the conductive templates with copper;
a passivation nozzle for applying an insulating material over the metalized patterns;
a digital microscope for capturing real-time images of the printing process; and
a control system for dynamically adjusting the parameters of the laser burner, the HEA electroplating nozzle, and the passivation nozzle based on the real-time images from the digital microscope.

18. The multifunctional printer head of claim 17, wherein the control system uses machine learning algorithms to optimize printing parameters based on the type of fabric and the desired circuit layout.

19. A method for optimizing the printing of electronic circuits on fabrics using a multifunctional printer system, comprising:
generating a conductive template on a fabric by burning the fabric surface with a laser burner to create carbonized conductive patterns;
metalizing the conductive template by applying copper using a dual-tube Hydrogen Evolution Assisted (HEA) electroplating nozzle, which dispenses and removes an electrolyte while generating hydrogen evolution at the cathode to enhance plating;
applying an insulating material over the metalized patterns using a passivation nozzle to passivate the surface of the conductor;
dynamically adjusting the parameters of the laser burner, the HEA electroplating nozzle, and the passivation nozzle based on real-time feedback from a digital microscope integrated with the control system; and
performing an iterative optimization process wherein the control system adjusts the printing parameters based on the color shade of the copper detected by the digital
microscope, correlating the shade with the resistivity of the printed copper to maintain optimal conductivity.
